(19) United States
(12) Patent Application Publication
(10) Pub. No.: US 2016/0380137 A1
(43) Pub. Date: Dec. 29, 2016

(54) LIGHT-RECEIVING DEVICE

(71) Applicant: Sumitomo Electric Industries, Ltd., Osaka-shi, Osaka (JP)

(72) Inventors: Kaoru SHIBATA, Itami-shi (JP); Kei FUJII, Itami-shi (JP); Takashi KYONO, Itami-shi (JP); Koji NISHIZUKA, Itami-shi (JP); Katsushi AKITA, Itami-shi (JP)

(21) Appl. No.: 15/039,519

(22) PCT Filed: Sep. 3, 2014
(86) PCT No.: PCT/JP2014/073142

§ 371 Date: May 26, 2016

(30) Foreign Application Priority Data
Nov. 27, 2013 (JP) 2013-244961

(51) Int. Cl. H01L 31/0352; H01L 31/0304; H01L 31/18; H01L 31/105

(52) U.S. Cl. CPC H01L 31/035236; H01L 31/105; H01L 31/03046; H01L 31/1844

(57) ABSTRACT

A light-receiving device includes: a group III-V compound semiconductor substrate having a first main surface; and a light-receiving layer formed on the first main surface, and the group III-V compound semiconductor substrate has a dislocation density of 10000 cm⁻² or less. Accordingly, the light-receiving device with low dark current is provided.

### TECHNICAL FIELD

The present invention relates to a light-receiving device, and particularly relates to a light-receiving device formed with a group III-V compound semiconductor substrate.

### BACKGROUND ART

The group III-V compound semiconductor has a band gap energy corresponding to the near-infrared region. Therefore, studies are in progress of a light-receiving device in which a group III-V compound semiconductor is used for a light-receiving layer for adapting the light-receiving device to communication, biometric inspection, night photography, or the like.

Generally, the light-receiving layer formed of the group III-V compound semiconductor is provided on a group III-V compound semiconductor substrate which can be lattice-matched with the group III-V compound semiconductor material.

Japanese Patent Laying-Open No. 2011-193024 discloses a light-receiving device in which a light-receiving layer having a multiquantum well structure of a group III-V compound semiconductor is formed on a group III-V compound semiconductor substrate. It also discloses, as an example of the light-receiving device, a light-receiving device in which a multiquantum well structure formed to include a pair of an indium gallium arsenide (InGaAs) layer and a gallium arsenide antimonide (GaAsSb) layer for example is formed on an InP substrate which is provided as a group III-V compound semiconductor substrate. It also discloses that InP and InGaAs are lattice-matched or InP and GaAsSb are lattice-matched with each other in this light-receiving device.

### CITATION LIST

### Patent Document

### PTD 1: Japanese Patent Laying-Open No. 2011-193024

### SUMMARY OF INVENTION

### Technical Problem

However, it has not been sufficiently clarified what relation exists between the dislocation density of the group III-V compound semiconductor substrate and dark current in the case where the material forming the group III-V compound semiconductor substrate and the material forming the light-receiving layer are lattice-matched with each other.

The present invention has been made for solving the above-described problem. A main object of the present invention is to provide a light-receiving device with reduced dark current.

### Solution to Problem

A light-receiving device according to the present invention includes: a group III-V compound semiconductor substrate having a first main surface; and a semiconductor layer stack formed on the first main surface, and the group III-V compound semiconductor substrate has a dislocation density of less than 10000 cm⁻².

### Advantageous Effects of Invention

In accordance with the present invention, a light-receiving device with sufficiently low dark current can be obtained.

### BRIEF DESCRIPTION OF DRAWINGS

FIG. 1 is a diagram for illustrating a light-receiving device according to the present embodiment.

FIG. 2 is a diagram for illustrating the light-receiving device according to the present embodiment.

FIG. 3 is a diagram for illustrating an epitaxial substrate according to the present embodiment.

FIG. 4 is a diagram for illustrating how to calculate the dislocation density of a group III-V compound semiconductor substrate in a light-receiving device and an epitaxial substrate according to the present embodiment.

FIG. 5 is a graph showing a relation between the dislocation density and the dark-current defect pixel ratio of an InP substrate in the present example.

FIG. 6 is a diagram for illustrating a modification of the light-receiving device according to the present embodiment.

### DESCRIPTION OF EMBODIMENTS

In the following, an embodiment of the present invention will be described based on the drawings. It should be noted that the same or corresponding parts in the drawings are denoted by the same reference numerals, and a description thereof will not be repeated.

[Description of the Embodiment of the Present Invention]

First, general features of the embodiment of the present invention are listed.

(1) A light-receiving device 100, 200 according to the present embodiment includes: a group III-V compound semiconductor substrate 1 having a first main surface 1a; and a light-receiving layer 3 located on first main surface 1a, and group III-V compound semiconductor substrate 1 has a dislocation density of 10000 cm⁻² or less.

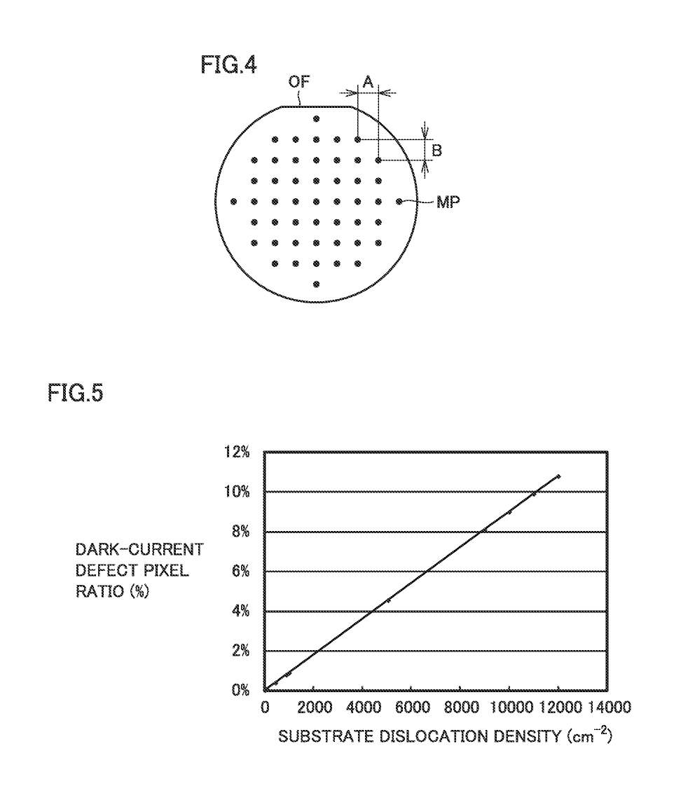

In the present embodiment, the dislocation density of group III-V compound semiconductor substrate 1 is expressed as the etch pit density (EPD). In the present embodiment, the dislocation density of group III-V compound semiconductor substrate 1 is an average value of respective EPD values measured at a plurality of measurement points MP (see FIG. 4) on first main surface 1a of group III-V compound semiconductor substrate 1 having an arbitrary outer diameter. A plurality of measurement points MP are set at intervals A (see FIG. 4) in the direction parallel with the orientation flat (hereinafter OF) and at intervals B (see FIG. 4) in the direction perpendicular to the OF. For example, interval A and interval B are each 5 mm. In this case, for example, if group III-V compound semiconductor substrate 1 has an outer diameter of 50 mm, the number of measurement points MP is 69 and, if group III-V compound semiconductor substrate 1 has an outer diameter of 100 mm, the number of measurement points MP is 256.

Thus, dark current caused by crystal defects such as dislocation of group III-V compound semiconductor substrate 1 can be reduced. Consequently, light-receiving device 100, 200 with sufficiently low dark current can be obtained.

If the dislocation density of group III-V compound semiconductor substrate 1 is more than 10000 cm⁻², light-receiving device 100, 200 including light-receiving layer 3 provided on this group III-V compound semiconductor substrate 1 has deteriorated light-receiving sensitivity and the dark-current defect pixel ratio is 10% or more. Therefore, this light-receiving device is not suitable for practical use. Namely, in the case where the dislocation density of group III-V compound semiconductor substrate 1 is 10000 cm⁻³ or less, deterioration of the light-receiving sensitivity of light-receiving device 100, 200 due to dark current can be suppressed, and the dark-current defect pixel ratio can be reduced to the extent that makes the light-receiving device applicable to practical use. It should be noted that “dark-current defect pixel ratio” herein refers to the ratio of the number of dark-current defect pixels to the total number of pixels per unit area.

(2) Regarding light-receiving device 100, 200 according to the present embodiment, preferably group III-V compound semiconductor substrate 1 has a dislocation density of 5000 cm⁻² or less.

Thus, dark current caused by crystal defects such as dislocation of group III-V compound semiconductor substrate 1 can further be reduced, and light-receiving device 100, 200 including light-receiving layer 3 provided on this group III-V compound semiconductor substrate 1 can have excellent light-receiving sensitivity. Moreover, the dark-current defect pixel ratio of light-receiving device 100, 200 can be reduced. For example, in the case where the total number of pixels per unit area is approximately 10⁵ cm⁻², the dark-current defect pixel ratio can be reduced to 5% or less. Furthermore, group III-V compound semiconductor substrate 1 having a dislocation density of 5000 cm⁻² or less has the advantages that this substrate is easy to fabricate and easy to obtain.

(3) Regarding light-receiving device 100, 200 according to the present embodiment, the group III-V compound semiconductor substrate may have a dislocation density of 1000 cm⁻² or more.

Thus, light-receiving device 100, 200 can have excellent light-receiving sensitivity as described above, and the dark-current defect pixel ratio of light-receiving device 100, 200 can sufficiently be reduced. In addition, a semi-insulating substrate doped with iron (Fe) for example can be used as group III-V compound semiconductor substrate 1. In the case where group III-V compound semiconductor substrate 1 is a semi-insulating substrate, absorption of the infrared light by free carriers is suppressed and therefore reduction of the intensity of the infrared light reaching light-receiving layer 3 can be suppressed. Consequently, the sensitivity of light-receiving device 100, 200 can be enhanced.

(4) Regarding light-receiving device 100, 200 according to the present embodiment, the group III-V compound semiconductor substrate may have a dislocation density of less than 1000 cm⁻².

Thus, light-receiving device 100, 200 can have excellent light-receiving sensitivity as described above, and the dark-current defect pixel ratio of light-receiving device 100, 200 can further be reduced. For example, in the case where the total number of pixels per unit area is approximately 10⁵ cm⁻², the dark-current defect pixel ratio can further be reduced to less than 1%.

(5) Regarding light-receiving device 100, 200 according to the present embodiment, the group III-V compound semiconductor substrate may have a dislocation density of less than 500 cm⁻².

Thus, light-receiving device 100, 200 can have excellent light-receiving sensitivity as described above, and the dark-current defect pixel ratio of light-receiving device 100, 200 can further be reduced. For example, in the case where the total number of pixels per unit area is approximately 10⁵ cm⁻², the dark-current defect pixel ratio can further be reduced to less than 0.5%.

(6) Regarding light-receiving device 100, 200 according to the present embodiment, preferably a material for group III-V compound semiconductor substrate 1 is one material selected from the group consisting of indium phosphide (InP), indium arsenide (InAs), indium antimonide (InSb), gallium antimonide (GaSb), and gallium arsenide (GaAs).

Thus, as a material forming light-receiving layer 3, a material suitable for receiving light in a predetermined wavelength region in the near-infrared region and the mid-infrared region can be selected from the group consisting of group III-V compound semiconductor materials which can be lattice-matched with the above-referenced materials. Consequently, the material which is to form light-receiving device 100, 200 can be selected from a wider range of materials.

(7) Regarding light-receiving device 100, 200 according to the present embodiment, group III-V compound semiconductor substrate 1 may contain, as an impurity, at least one element selected from the group consisting of silicon (Si), sulfur (S), selenium (Se), tellurium (Te), iron (Fe), chromium (Cr), and tin (Sn).

In the case where an impurity is added to group III-V compound semiconductor substrate 1, the dislocation density of group III-V compound semiconductor substrate 1 could be influenced by the kind of the impurity. For example, while group III-V compound semiconductor substrate 1 formed of InP with Fe added thereto can have a dislocation density of approximately 1000 cm⁻² or more and 10000 cm⁻² or less, this dislocation density is difficult to be reduced to less than 500 cm⁻². In contrast, group III-V compound semiconductor substrate 1 formed of InP with S added thereto can have a dislocation density of less than 1000 cm⁻² and can still have a dislocation density of less than 500 cm⁻². As seen from this, group III-V compound semiconductor substrate 1 having a dislocation density of a predetermined value which is 10000 cm⁻³ or less can contain, as an impurity, any element selected from the group consisting of Si, S, Se, Te, Fe, Cr, and Sn, depending on the value of the dislocation density to be achieved.

(8) Regarding light-receiving device 100, 200 according to the present embodiment, light-receiving layer 3 may have a type-II multiquantum well structure.

Thus, light-receiving device 100, 200 can receive light in a wide wavelength region which can be determined by the composition and the combination of materials forming light-receiving layer 3 and the thickness of light-receiving layer 3. Therefore, these parameters can be controlled to enable the light-receiving device to receive light in a predetermined wavelength region in the near-infrared region and the mid-infrared region, while materials having a larger band gap energy are used for the light-receiving layer as compared with the case where the light-receiving layer is formed of a single material. It should be noted that the type-II multiquantum well structure refers to “a quantum well structure in which transition occurs between a conduction band of one of the materials forming the quantum well structure and the valence band of the other material.”

(9) Regarding light-receiving device 100, 200 according to the present embodiment, any one of a pair of indium gallium arsenide (InGaAs) and gallium arsenide antimonide (GaAsSb) and a pair of InAs and GaSb may be used to form the multiquantum well structure of light-receiving layer 3.

Thus, in the case where group III-V compound semiconductor substrate 1 is formed of InP for example, InGaAs and GaAsSb can be lattice-matched with InP substrate 1, and therefore generation of crystal defects in light-receiving layer 3 due to lattice mismatch can be suppressed. As to InAs and GaSb as well, these materials can be lattice-matched with InP substrate 1, and can produce similar effects. Consequently, light-receiving device 100, 200 formed of these materials can be expected to have low dark current.

(10) Light-receiving device 100, 200 according to the present embodiment further includes a group III-V compound semiconductor layer located on the light-receiving layer, and preferably the group III-V compound semiconductor layer includes a window layer.

Namely, light-receiving device 100, 200 according to the present embodiment may further include window layer 5 formed of a group III-V compound semiconductor and located opposite to group III-V compound semiconductor substrate 1 with light-receiving layer 3 interposed therebetween. Thus, the infrared light enters light-receiving layer 3 through window layer 5, and therefore, window layer 5 may be adapted to suppress absorption of the infrared light and group III-V compound semiconductor substrate 1 may be formed for example to have a high carrier concentration. Even in light-receiving device 100, 200 obtained using group III-V compound semiconductor substrate 1 to which a dopant such as S for example is added and which has a high carrier concentration, the dislocation density of group III-V compound semiconductor substrate 1 is kept to be a predetermined value or less as described above. Therefore, light-receiving device 100, 200 can have excellent light-receiving sensitivity and the dark-current defect pixel ratio of light-receiving device 100, 200 can sufficiently be reduced. Moreover, window layer 5 can suppress surface leakage current which is one cause of dark current. Consequently, dark current of light-receiving device 100, 200 can more effectively be suppressed, and the dark-current defect pixel ratio can further be reduced.

(11) Regarding light-receiving device 100, 200 according to the present embodiment, preferably window layer 5 is formed of a material having a greater band gap energy than a band gap energy of light-receiving layer 3. Here, the band gap energy of light-receiving layer 3 refers to effective band gap energy of light-receiving layer 3, and corresponds to transition energy between the conduction band of one of the materials forming the quantum well structure and the valence band of the other material. Thus, reduction of the intensity of the infrared light entering light-receiving layer 3 due to absorption of the infrared light by window layer 5 can sufficiently be suppressed.

(12) Regarding light-receiving device 100, 200 according to the present embodiment, window layer 5 may be formed of InP.

Thus, the wide band gap of InP enables sufficient suppression of reduction of the intensity of the infrared light entering light-receiving layer 3, due to absorption of the infrared light by window layer 5.

[Details of the Embodiment of the Present Invention]

Next, details of the embodiment of the present invention will be described.

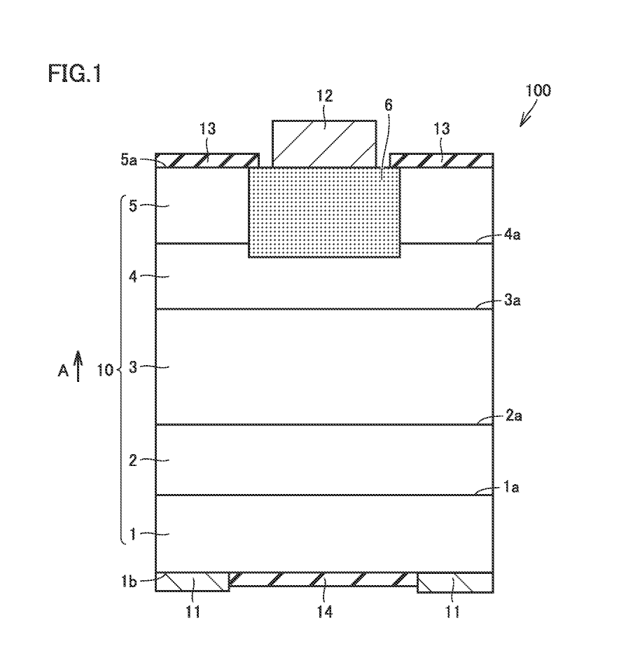

Referring to FIG. 1, a light-receiving device 100 according to the present embodiment will be described. Light-receiving device 100 is a PIN photodiode. Specifically, light-receiving device 100 is a PIN photodiode in which a p-type diffusion region 6, an n-type electrode 11, a p-type electrode 12, and an insulating film 13 are formed on an epitaxial substrate 10 including a group III-V compound semiconductor substrate 1, a buffer layer 2, a light-receiving layer 3, a diffusion concentration distribution adjustment layer 4, and a window layer 5.

Group III-V compound semiconductor substrate 1 may be formed of any group III-V compound semiconductor material, and is formed for example of indium phosphide (InP). Group III-V compound semiconductor substrate 1 has a first main surface 1a and a back surface 1b located opposite to first main surface 1a, and is connected through first main surface 1a to buffer layer 2. The plane orientation of first main surface 1a is the (100) plane for example. Group III-V compound semiconductor substrate 1 has the n-type conductivity. An n-type dopant contained in group III-V compound semiconductor substrate 1 is sulfur (S) for example. Group III-V compound semiconductor substrate 1 has a carrier concentration of 1×10¹⁸ cm⁻³ or more and 8×10¹⁸ cm⁻³ or less.

Group III-V compound semiconductor substrate 1 has a dislocation density of 10000 cm⁻² or less, preferably 5000 cm⁻² or less. In the present embodiment, group III-V compound semiconductor substrate 1 has a dislocation density of less than 500 cm⁻². Namely, in the case where the number of pixels of light-receiving device 100 per unit area is 10⁵ cm⁻² and the EPD is 450 cm⁻², a dark-current defect pixel ratio of 0.45% can be achieved.

Buffer layer 2 is provided on first main surface 1a of group III-V compound semiconductor substrate 1. Buffer layer 2 may be formed of any group III-V compound semiconductor material as long as there is no lattice mismatch between this group III-V compound semiconductor material forming the buffer layer and the material forming group III-V compound semiconductor substrate 1. For example, buffer layer 2 is formed of indium gallium arsenide (InGaAs). Buffer layer 2 has a second main surface 2a located opposite to its surface abutting on first main surface 1a of group III-V compound semiconductor substrate 1, and is connected through second main surface 2a to light-receiving layer 3. Buffer layer 2 has the n-type conductivity. Buffer layer 2 has a carrier concentration for example of 1×10¹⁷ cm⁻³ or more and 5×10¹⁸ cm⁻³ or less. Buffer layer 2 has a thickness for example of 0.01 μm or more and 5 μm or less.

Light-receiving layer 3 has a type-II multiquantum well structure. Specifically, approximately 250 pairs, which are each a stacked pair of an InGaAs layer and a gallium arsenide antimonide (GaAsSb) layer for example, are stacked to form light-receiving layer 3. The InGaAs layer and the GaAsSb layer each have a thickness of 1 nm or more and 10 nm or less. Light-receiving layer 3 has a third main surface 3a located opposite to its surface abutting on second main surface 2a of buffer layer 2, and is connected through third main surface 3a to diffusion concentration distribution adjustment layer 4. Each of the InGaAs layer and the GaAsSb layer is not intentionally doped.

Diffusion concentration distribution adjustment layer 4 may be formed of any group III-V compound semiconductor material, and is formed for example of InGaAs. Diffusion concentration distribution adjustment layer 4 has a fourth main surface 4a located opposite to its surface abutting on third main surface 3a of light-receiving layer 3, and is connected through fourth main surface 4a to window layer 5. Diffusion concentration distribution adjustment layer 4 is not intentionally doped. In a stack direction A, the thickness of diffusion concentration distribution adjustment layer 4 is for example 0.5 μm or more and 3 μm or less.

Window layer 5 may be formed of any group III-V compound semiconductor material, and is formed for example of InP. Window layer 5 has a fifth main surface 5a located opposite to its surface abutting on fourth main surface 4a of diffusion concentration distribution adjustment layer 4. In stack direction A, the thickness of window layer 5 is for example 0.5 μm or more and 3 μm or less.

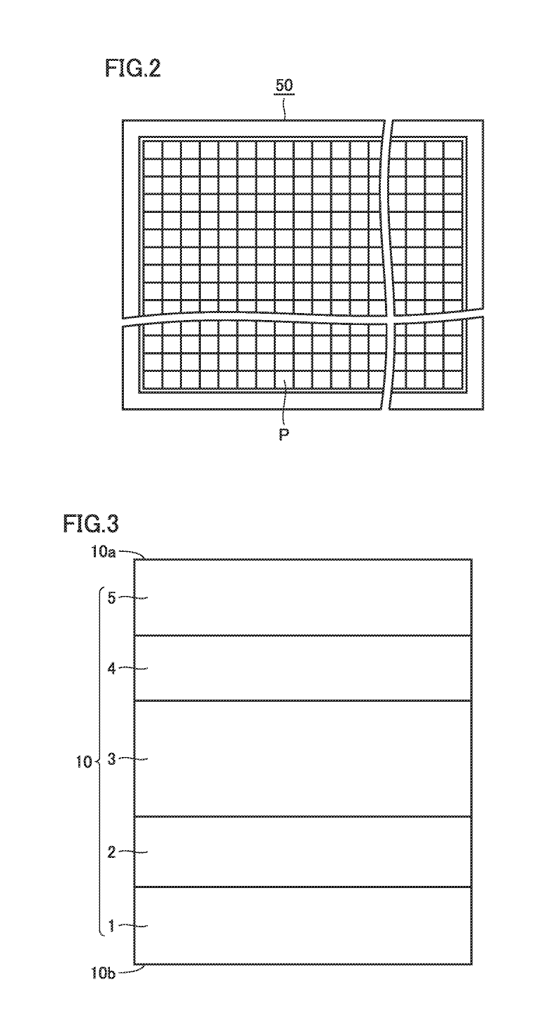

In a predetermined region on fifth main surface 5a, p-type diffusion region 6 is formed. Specifically, across a plurality of regions where pixels P (see FIG. 2) are arranged as planar-type light-receiving devices, p-type diffusion region 6 is formed. P-type diffusion region 6 contains zinc (Zn) as a p-type impurity, and is formed through selective diffusion of Zn from fifth main surface 5a.

P-type diffusion region 6 is formed perpendicularly to fifth main surface 5a and extends through window layer 5 into a predetermined region in diffusion concentration distribution adjustment layer 4. Namely, p-type diffusion region 6 is not formed in light-receiving layer 3, and the lower end (Zn diffusion front) in stack direction A of p-type diffusion region 6 is located inside diffusion concentration distribution adjustment layer 4, not in light-receiving layer 3. In other words, there is no high-concentration introduction of Zn in light-receiving layer 3. In the direction along fifth main surface 5a, p-type diffusion region 6 is formed across a plurality of regions where pixels are arranged as planar-type light-receiving devices.

N-type electrode 11 is provided on back surface 1b of group III-V compound semiconductor substrate 1. N-type electrode 11 may be formed of any material which can be ohmic-joined to group III-V compound semiconductor substrate 1, and is formed for example of Au/Ge/Ni. N-type electrode 11 may be formed on a part of back surface 1b. In a region where n-type electrode 11 is not formed on back surface 1b, an anti-reflection film 14 may be formed. The material forming anti-reflection film 14 is for example silicon nitride (SiN), silicon oxide (SiO₂), or silicon oxynitride (SiON).

P-type electrode 12 is provided on fifth main surface 5a of window layer 5. P-type electrode 12 may be formed of a material which can be ohmic-joined to p-type diffusion region 6 having the p-type conductivity, and is formed for example of Au/Zn.

In a region where p-type electrode 12 is not formed on fifth main surface 5a, insulating film 13 is formed. The material forming insulating film 13 is for example silicon oxide (SiO₂) or SiN.

Referring to FIG. 2, in the case where light-receiving device 100 is structured in the form of a light-receiving device array 50 including a plurality of pixels P, the number of p-type diffusion regions 6 and the number of p-type electrodes 12 are each equal to the number of pixels. Regarding each light-receiving device 100 in the present embodiment, adjacent p-type diffusion regions 6 are formed to be separated from each other. Therefore, the p-type diffusion regions 6 can be formed without providing device isolation grooves.

Next, a description will be given of an operation of light-receiving device 100 according to the present embodiment. First, a predetermined reverse bias voltage can be applied between n-type electrode 11 and p-type electrode 12 of light-receiving device 100 to thereby deplete not only light-receiving layer 3 but also a part of diffusion concentration distribution adjustment layer 4 in stack direction A. Light to be measured (near-infrared light or mid-infrared light for example) is applied from fifth main surface 5a of window layer 5 and transmitted through window layer 5 and diffusion concentration distribution adjustment layer 4 each formed of a wide band-gap group III-V compound semiconductor material and then enters light-receiving layer 3. In light-receiving layer 3, the light is absorbed to generate electron-hole pairs. An electric field generated in the depletion layer causes electrons to move into the n-type region (buffer layer 2 and n-type electrode 11 through group III-V compound semiconductor substrate 1), and causes holes to move into the p-type region (through p-type diffusion region 6 into p-type electrode 12), and read as electric current.

While light-receiving device 100 in the present embodiment is configured on the premise that light to be measured (near-infrared light or mid-infrared light for example) is applied from fifth main surface 5a of window layer 5, the light-receiving device is not limited to this. For example, light to be measured may be applied from back surface 1b of group III-V compound semiconductor substrate 1. In this case, light is transmitted through group III-V compound semiconductor substrate 1 and buffer layer 2 and enters light-receiving layer 3. The light is absorbed in light-receiving layer 3 to generate electron-hole pairs. An electric field generated in the depletion layer causes electrons to move into the n-type region (buffer layer 2 and n-type electrode 11 through group III-V compound semiconductor substrate 1), and causes holes to move into the p-type region (p-type electrode 12 through p-type diffusion region 6), and then read as electric current.

Referring next to FIG. 3, a description will be given of epitaxial substrate 10 according to the present embodiment. Epitaxial substrate 10 in the present embodiment is an epitaxial substrate used for manufacturing light-receiving device 100 in the present embodiment. Epitaxial substrate 10 includes group III-V compound semiconductor substrate 1, buffer layer 2, light-receiving layer 3, diffusion concentration distribution adjustment layer 4, and window layer 5, as described above. In epitaxial substrate 10, the dislocation density of group III-V compound semiconductor substrate 1 is kept low, such as a dislocation density of less than 500 cm⁻² as described above.

Next, a description will be given of a method of manufacturing light-receiving device 100 according to the present embodiment.

Initially, epitaxial substrate 10 is prepared (step (S10)). Specifically, group III-V compound semiconductor substrate 1 having the n-type conductivity and formed of InP is prepared first. Group III-V compound semiconductor substrate 1 is prepared so that the dislocation density is less than 500 cm⁻². Group III-V compound semiconductor substrate 1 having a dislocation density of less than 500 cm⁻² can be produced for example in accordance with the vapor pressure-controlled Czochralski method (VCZ method).

Next, the MOVPE method is used to epitaxially grow buffer layer 2 on group III-V compound semiconductor substrate 1. Specifically, on first main surface 1a of group III-V compound semiconductor substrate 1, buffer layer 2 which is formed of n-type-impurity-doped InGaAs is epitaxially grown. Next, light-receiving layer 3 is epitaxially grown. Specifically, on second main surface 2a of buffer layer 2, an InGaAs layer and a GaAsSb layer are alternately grown without intentional doping with an impurity (without feeding a dopant gas). Next, diffusion concentration distribution adjustment layer 4 is grown. Specifically, on third main surface 3a of light-receiving layer 3, diffusion concentration distribution adjustment layer 4 formed of InGaAs is grown without intentional doping with an impurity (without feeding a dopant gas). Next, window layer 5 is grown. Specifically, on fourth main surface 4a of diffusion concentration distribution adjustment layer 4, window layer 5 formed of InP is grown without intentional doping with an impurity (without feeding a dopant gas). In this way, epitaxial substrate 10 in the present embodiment shown in FIG. 3 is prepared.

Next, p-type diffusion region 6 is formed (step (S20)). Specifically, on fifth main surface 5a of window layer 5, a diffusion mask pattern formed for example of a silicon nitride (SiN) film is formed first. The diffusion mask pattern has an opening in a region where p-type diffusion region 6 is to be formed. Next, from the opening of the diffusion mask pattern, Zn is selectively diffused in window layer 5 and diffusion concentration distribution adjustment layer 4. The diffusion concentration and the diffusion depth are controlled so as not to cause p-type diffusion region 6 to reach light-receiving layer 3.

Next, n-type electrode 11 and anti-reflection film 14 are formed on back surface 1b of group III-V compound semiconductor substrate 1, and p-type electrode 12 and insulating film 13 are formed on fifth main surface 5a (step (S30)). N-type electrode 11 is provided to make ohmic contact with group III-V compound semiconductor substrate 1, and p-type electrode 12 is provided to make ohmic contact with p-type diffusion region 6. Each electrode can be formed by any film formation method. In this way, light-receiving layer 100 in the present embodiment can be obtained.

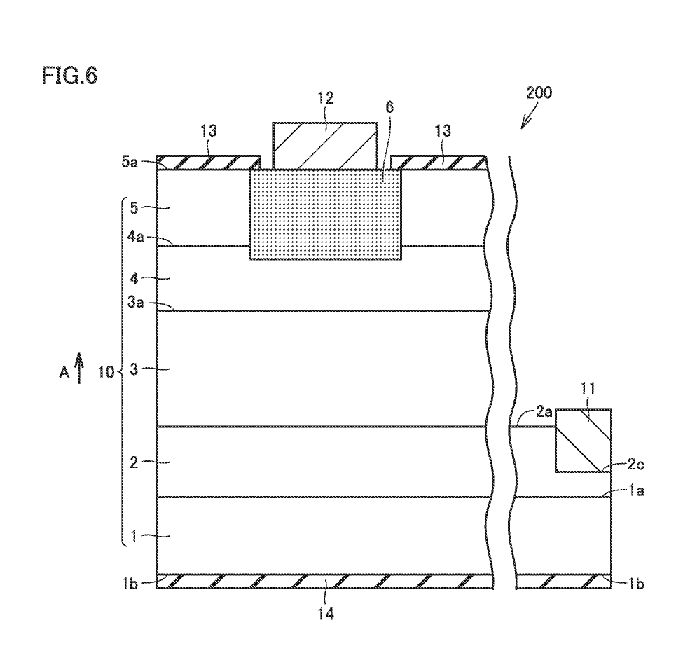

While the method of manufacturing a light-receiving device according to the present embodiment forms n-type electrode 11 on back surface 1b of group III-V compound semiconductor substrate 1, the method is not limited to this. Referring to FIG. 6, n-type electrode 11 of light-receiving device 200 may be formed for example to make ohmic contact with buffer layer 2 which is an epitaxial layer. Specifically, epitaxial substrate 10 is partially etched from fifth main surface 5a to expose buffer layer 2, and n-type electrode 11 may be formed on an exposed etched surface 2c. Alternatively, group III-V compound semiconductor substrate 1 may be exposed and n-type electrode 11 may be formed on exposed substrate 1. In these cases as well, a predetermined reverse bias voltage can be applied between n-type electrode 11 and p-type electrode 12 to deplete not only light-receiving layer 3 but also a part of diffusion concentration distribution adjustment layer 4 in stack direction A. Consequently, similar effects to those of the light-receiving device in the present embodiment can be obtained. In this case, anti-reflection film 14 may be formed on the whole back surface 1b of group III-V compound semiconductor substrate 1.

Next, functions and effects of light-receiving device 100, 200 according to the present embodiment will be described. Light-receiving device 100, 200 in the present embodiment is formed on group III-V compound semiconductor substrate 1 having a dislocation density of less than 500 cm⁻². Therefore, dark current caused by crystal defects such as dislocation of group III-V compound semiconductor substrate 1 can sufficiently be reduced. Consequently, light-receiving device 100, 200 can have excellent light-receiving sensitivity and the dark-current defect pixel ratio can be kept sufficiently low. For example, in the case where the total number of pixels per unit area is approximately 10⁵ cm⁻², the dark-current defect pixel ratio can be reduced to less than 0.5%.

Moreover, light-receiving device 100, 200 in the present embodiment is formed on group III-V compound semiconductor substrate 1 formed of InP, and therefore, light-receiving layer 3 can be formed of a group III-V compound semiconductor material such as InGaAs or GaAsSb which can be lattice-matched with the InP substrate. Light-receiving layer 3 formed as a type-II multiquantum well structure in which a pair of an InGaAs layer and a GaAsSb layer is included has the light-receiving sensitivity for light in a predetermined wavelength region in the near-infrared region and the mid-infrared region. At this time, each material forming light-receiving layer 3 is lattice-matched with the InP substrate as described above, and therefore, dark current caused by crystal defects can sufficiently be reduced. Consequently, light-receiving device 100, 200 can have high light-receiving sensitivity for light in a predetermined wavelength region in the near-infrared region and the mid-infrared region.

Moreover, in group III-V compound semiconductor substrate 1 in the present embodiment, S is added as an impurity, and therefore, the substrate can have a dislocation density of less than 500 cm⁻² while the substrate has the n-type conductivity. Accordingly, group III-V compound semiconductor substrate 1 can make ohmic contact with n-type electrode 11, and dark current caused by crystal defects such as dislocation of group III-V compound semiconductor substrate 1 can be reduced. Consequently, light-receiving device 100, 200 with sufficiently low dark current can be obtained.

Moreover, light-receiving device 100, 200 in the present embodiment can be fabricated easily by using epitaxial substrate 10 including group III-V compound semiconductor substrate 1 as described above.

### Example

In the following, a description will be given of an example according to the present embodiment.

<Samples>

As light-receiving devices in the example, light-receiving devices of Samples 1 to 5 were formed each having a similar structure to light-receiving device 200 in the present embodiment, in accordance with the method of manufacturing a light-receiving device in the present embodiment, using five InP substrates having respective dislocation densities different from each other, namely 450 cm⁻², 900 cm⁻², 1000 cm⁻², 5000 cm⁻², and 10000 cm⁻². The light-receiving devices of Samples 1 to 5 were formed so that one pixel had a two-dimensional size of 30 μm². Moreover, the InP substrate had an outer diameter of 50 mm, and the dislocation density of the InP substrate was calculated as an average value of EPD values measured at respective 69 measurement points on the first main surface that were arranged at intervals A and at intervals B which were each 5 mm as shown in FIG. 4.

For the light-receiving device of Sample 1, an InP substrate having a dislocation density of 450 cm⁻², containing S added as an impurity, and having a carrier concentration of 5×10¹⁸ cm⁻³ was prepared first. Next, the MOCVD method was used to grow, on the InP substrate, a buffer layer formed of InGaAs, a light-receiving layer having a type-II multiquantum well structure in which a pair of InGaAs and GaAsSb was included, diffusion concentration distribution adjustment layer 4 formed of InGaAs, and a window layer formed of InP. In an epitaxial substrate obtained in this way, Zn was selectively diffused to form a p-type diffusion region. Here, the p-type diffusion region was formed not to reach the light-receiving layer. Next, an n-type electrode, a p-type electrode, and an insulating film were formed. In this way, the light-receiving device of Sample 1 having a similar structure to light-receiving device 100 in the present embodiment shown in FIG. 1 was obtained.

For the light-receiving device of Sample 2, an InP substrate having a dislocation density of 900 cm⁻², containing S added as an impurity, and having a carrier concentration of 5×10¹⁸ cm⁻³ was prepared first. Subsequently, a process basically similar to the method of manufacturing a light-receiving device in the present embodiment (similar to above-described Sample 1) was performed to obtain the light-receiving device of Sample 2 having a similar structure to light-receiving device 100 in the present embodiment shown in FIG. 1.

For the light-receiving device of Sample 3, a high-resistance InP substrate having a dislocation density of 1000 cm⁻² and containing Fe added as an impurity was prepared first. Next, the MOCVD method was used to grow, on the above-described InP substrate, a buffer layer formed of InGaAs, a light-receiving layer having a type-II multiquantum well structure in which a pair of InGaAs and GaAsSb was included, diffusion concentration distribution adjustment layer 4 formed of InGaAs, and a window layer formed of InP. In an epitaxial substrate obtained in this way, Zn was selectively diffused to form a p-type diffusion region. Here, the p-type diffusion region was formed not to reach the light-receiving layer. Next, an n-type electrode, a p-type electrode, and an insulating film were formed. The n-type electrode was formed on the buffer layer which was exposed by partially etching the epitaxial layer. In this way, the light-receiving device of Sample 3 having a similar structure to light-receiving device 200 in the present embodiment shown in FIG. 6 was obtained.

For the light-receiving device of Sample 4, a high-resistance InP substrate having a dislocation density of 5000 cm⁻² and containing Fe added as an impurity was prepared first. Subsequently, a process basically similar to the method of manufacturing a light-receiving device in the present embodiment (similar to above-described Sample 3) was performed to obtain the light-receiving device of Sample 4 having a similar structure to light-receiving device 200 in the present embodiment shown in FIG. 6.

For the light-receiving device of Sample 5, a high-resistance InP substrate having a dislocation density of 10000 cm⁻² and containing Fe added as an impurity was prepared first. Subsequently, a process basically similar to the method of manufacturing a light-receiving device in the present embodiment (similar to above-described Sample 3) was performed to obtain the light-receiving device of Sample 5 having a similar structure to light-receiving device 200 in the present embodiment shown in FIG. 6.

Moreover, as a light-receiving device of a comparative example, the light-receiving device of Sample 6 having a similar structure to light-receiving device 200 in the present embodiment was formed in accordance with the method of manufacturing a light-receiving device in the present embodiment, using an InP substrate having a dislocation density of 11000 cm⁻². Specifically, a high-resistance InP substrate containing Fe added as an impurity was first prepared. On this InP substrate, a process similar to Samples 3 to 5 was performed to thereby obtain the light-receiving device of Sample 6 basically having a similar structure to Samples 3 to 5.

<Evaluation>

To the light-receiving devices of Samples 1 to 6 prepared in the above-described manner, near-infrared light having a wavelength of 2.2 μm was applied, and the light-receiving sensitivity of each light-receiving device was measured. Specifically, with a reverse bias voltage Vr of −1 V applied between the n-type electrode and the p-type electrode, light having a wavelength of 2.2 μm was applied to the light-receiving device. Moreover, from the dislocation density and the number of pixels per unit area of the InP substrate used for each of the light-receiving devices of Samples 1 to 6, the dark-current defect pixel ratio was calculated. The dark-current defect pixel was defined as a pixel having a dark current density of 1 μA/cm² or more at an environmental temperature of 60° C.

<Results>

The results of the evaluation are shown in Table 1.

TABLE 1

| | Sample 1 | Sample 2 | Sample 3 | Sample 4 | Sample 5 | Sample 6 |
|---|---|---|---|---|---|---|
| dislocation density of InP | 450 | 900 | 1000 | 5000 | 10000 | 11000 |
| substrate (cm⁻²) | | | | | | |
| dopant | S | S | Fe | Fe | Fe | Fe |
| light-receiving sensitivity | 1.2 | 1.2 | 1.5 | 1.5 | 1.0 | 0.2 |
| (A/W) | | | | | | |
| rating of light-receiving | B | B | A | A | B | D |
| sensitivity | | | | | | |
| dark-current defect pixel | 0.4 | 0.8 | 1.0 | 4.5 | 9.0 | 10.0 |
| ratio (%) | | | | | | |
| rating of dark-current | A | B | C | C | C | D |
| defect pixel ratio | | | | | | |
| overall rating | A | B | B | B | C | D |

The light-receiving device of Sample 6 has a high dark-current defect pixel ratio of 10.0% and a low light-receiving sensitivity of 0.2 A/W and therefore does not meet the characteristics required for the light-receiving device.

While the light-receiving device of Sample 5 has a somewhat high dark-current defect pixel ratio of 9.0%, this light-receiving device has an excellent light-receiving sensitivity of 1.0 A/W for the near-infrared light of 2.2 μm. While the light-receiving device of Sample 4 has a somewhat high dark-current defect pixel ratio of 4.5%, this light-receiving device has a remarkably excellent light-receiving sensitivity of 1.5 A/W for the near-infrared light of 2.2 μm. The light-receiving device of Sample 3 has a low dark-current defect pixel ratio of 1.0% and a remarkably excellent light-receiving sensitivity of 1.5 A/W for the near-infrared light of 2.2 μm. The light-receiving device of Sample 2 has a low dark-current defect pixel ratio of 0.8% and an excellent light-receiving sensitivity of 1.2 A/W for the near-infrared light of 2.2 μm. The light-receiving device of Sample 1 has a remarkably low dark-current defect pixel ratio of 0.4% and an excellent light-receiving sensitivity of 1.2 A/W for the near-infrared light of 2.2 μm.

It can be confirmed that the light-receiving devices of Samples 1 to 5 each have a lower dark-current defect pixel ratio and a higher light-receiving sensitivity relative to the light-receiving device of Sample 6. The light-receiving devices of Samples 3 and 4 each have a lower dark-current defect pixel ratio and a higher light-receiving sensitivity relative to the light-receiving devices of Samples 5 and 6. The reason for this is considered as the fact that the dark current caused by crystal defects such as dislocation can be sufficiently reduced as the dislocation density of the InP substrate is lower.

Moreover, it can be confirmed that the light-receiving devices of Samples 1 and 2 can have the dark-current defect pixel ratio kept still lower relative to the light-receiving devices of Samples 3 and 4, and can have a higher light-receiving sensitivity relative to the light-receiving devices of Samples 5 and 6.

It can be confirmed that the light-receiving devices of Samples 3 and 4 each have a higher light-receiving sensitivity relative to the light-receiving devices of Samples 1 and 2. The reason for this is considered as the fact the semi-insulating InP substrate containing Fe added as a dopant is used and therefore the dark current can be kept low. Further, referring to FIG. 5, it is confirmed that the dislocation density of the InP substrate and the dark-current defect pixel ratio have a proportional relation therebetween. The horizontal axis of FIG. 5 represents the dislocation density (unit: cm⁻²) of the InP substrate used for manufacturing the light-receiving device, and the vertical axis thereof represents the dark-current defect pixel ratio (unit: %) of the obtained light-receiving device. Accordingly, it can be confirmed from the results of evaluation of the present example that the light-receiving device can be fabricated using a substrate with a low dislocation density to thereby keep low the dark-current defect pixel ratio of the obtained light-receiving device.

While the embodiment and example of the present invention have been described, the above-described embodiment can be modified in various ways. Moreover, the scope of the present invention is not limited to the above-described embodiment and example. It is intended that the scope of the present invention is defined by claims, and encompasses all variations equivalent in meaning and scope to the claims.

### INDUSTRIAL APPLICABILITY

The present invention is particularly advantageously applied to a light-receiving device capable of receiving light in the near-infrared region and the mid-infrared region.

### REFERENCE SIGNS LIST

1 group III-V compound semiconductor substrate; 1a first main surface; 2 buffer layer; 2a second main surface; 3 light-receiving layer; 3a third main surface; 4 diffusion concentration distribution adjustment layer; 4a fourth main surface; 5 window layer; 5a fifth main surface; 6 p-type diffusion region; 10 epitaxial substrate; 10b back surface; 11 n-type electrode; 12 p-type electrode; 13 insulating film; 14 anti-reflection film; 100 light-receiving device

1. A light-receiving device comprising:
a group III-V compound semiconductor substrate having a first main surface; and
a light-receiving layer located on the first main surface and formed of a group III-V compound semiconductor,
the group III-V compound semiconductor substrate having a dislocation density of 10000 cm⁻² or less.

2. The light-receiving device according to claim 1, wherein the group III-V compound semiconductor substrate has a dislocation density of 5000 cm⁻² or less.

3. The light-receiving device according to claim 1, wherein the group III-V compound semiconductor substrate has a dislocation density of 1000 cm⁻² or more.

4. The light-receiving device according to claim 1, wherein the group III-V compound semiconductor substrate has a dislocation density of less than 1000 cm⁻².

5. The light-receiving device according to claim 1, wherein the group III-V compound semiconductor substrate has a dislocation density of less than 500 cm⁻².

6. The light-receiving device according to claim 1, wherein a material for the group III-V compound semiconductor substrate is one material selected from the group consisting of indium phosphide (InP), indium arsenide (InAs), indium antimonide (InSb), gallium antimonide (GaSb), and gallium arsenide (GaAs).

7. The light-receiving device according to claim 1,
wherein the group III-V compound semiconductor substrate contains, as an impurity, at least one element selected from the group consisting of silicon (Si), sulfur (S), selenium (Se), tellurium (Te), iron (Fe), chromium (Cr), and tin (Sn).

8. The light-receiving device according to claim 1, wherein the light-receiving layer has a type-II multiquantum well structure.

9. The light-receiving device according to claim 8, wherein any one of a pair of indium gallium arsenide (InGaAs) and gallium arsenide antimonide (GaAsSb) and a pair of InAs and GaSb is used to form the multiquantum well structure of the light-receiving layer.

10. The light-receiving device according to claim 1, further comprising a group III-V compound semiconductor layer located on the light-receiving layer, wherein
the group III-V compound semiconductor layer includes a window layer.

11. The light-receiving device according to claim 10, wherein the window layer is formed of a material having a greater band gap energy than a band gap energy of the light-receiving layer.

12. The light-receiving device according to claim 11, wherein the window layer is formed of InP.
